(19) United States
(12) Patent Application Publication
(10) Pub. No.: US 2025/0284854 A1
(43) Pub. Date: Sep. 11, 2025

(54) PRE-CONTROL AND MONITORING METHOD AND SYSTEM FOR WHOLE PROCESS OF ACTUAL GROUTING ENGINEERING BASED ON DIGITAL GEOLOGICAL MODEL

(71) Applicant: SHANDONG UNIVERSITY, Jinan (CN)

(72) Inventors: Zhenhao Xu, Jinan (CN); Shucai Li, Jinan (CN); Dongdong Pan, Jinan (CN); Yihui Li, Jinan (CN); Zehua Bu, Jinan (CN); Shengzhe Zhao, Jinan (CN); Yichi Zhang, Jinan (CN); Shuo Tai, Jinan (CN)

(73) Assignee: SHANDONG UNIVERSITY, Jinan (CN)

(21) Appl. No.: 19/074,012

(22) Filed: Mar. 7, 2025

(30) Foreign Application Priority Data
Mar. 7, 2024 (CN) 2024102568802
Mar. 7, 2024 (CN) 2024102608674

(51) Int. Cl. G06F 30/13

(52) U.S. Cl. CPC G06F 30/13

(57) ABSTRACT

The invention provides a pre-control and monitoring method for a whole process of actual grouting engineering based on digital geological model, comprising: extracting discontinuous fracture surfaces in a geologic body structure, to build a underground geologic body structure model; build a multi-source geologic body attribute model, optimizing and solving grouting simulations of a disaster high-risk region by using multiphase flow calculation method, and controlling grouting equipment by using optimized grouting parameters to carry out an actual grouting engineering; obtaining a multi-factor diffusion range of variable coefficients by adjusting physical values of the parameters in the grouting simulation and attribute data structure model by using a control variable method, learning and capturing complex mapping relationship between different parameters by using a neural network, optimizing the grouting parameters in the actual engineering in real-time, so as to realize the pre-controlling, monitoring and optimization of the whole process of the actual grouting engineering.

### CROSS-REFERENCE TO RELATED APPLICATIONS

This application claims priority benefits to Chinese Patent Application No. 202410256880.2, filed on Mar. 7, 2024, entitled “A Pre-control and Analysis Method and System for Multimodal Grouting Based on Digital Geological Model,” and another Chinese Patent Application No. 202410260867.4, filed on Mar. 7, 2024, entitled “A Criteria of Physical Placement of Sensor Based on Digital Twin in Grouting Engineering and Intelligent Optimization Method and System Thereof”, with the China National Intellectual Property Administration (CNIPA). The entirety of each of the above-mentioned patent applications is hereby incorporated by reference herein and made a part of this specification.

### TECHNICAL FIELD

The invention relates to the technical field of digital geological models, in particular to a pre-control and monitoring method and system for a whole process of an actual grouting engineering based on digital geological model.

### BACKGROUND

The statements in this section merely provide background information related to the present invention and do not necessarily constitute prior art.

The rapid development of underground engineering brings more extensive utilization of underground space. However, the complexity of underground geological environment brings new challenges to construction of the underground engineering. Compared with the aboveground space, there are more diversified and complex geological characteristics under the ground, and there are still a series of problems in dealing with heterogeneous data from multiple sources and digital geological modeling in current grouting pre-control methods of underground engineering, especially when facing with massive heterogeneous data from multiple dimensions and different types. The current digital display method can only present a single attribute, while building a multi-attribute model is limited by insufficient data and time-consuming problems. This limits the accuracy and comprehensiveness of underground engineering pre-control and analysis solution.

Building in complex underground environment, especially passing through water-rich fracture region, active fault and weak surrounding rock, the underground engineering faces the risk of water inrush and mud collapse. Grouting, as a common geological disaster prevention method, can effectively deal with all kinds of underground engineering disasters. However, there are some problems in grouting. Such as, a process of the grouting is much hidden, it is difficult to visualize a diffusion process of grouting slurry and accurately judge an influence of grouting parameters on prevention and control effect; and, the selection of existing grouting projects usually depends on manual experience, and there is no intelligent grouting parameter optimization solution.

The current three-dimensional (3D) geological modeling methods need to process all kinds of geological data uniformly, but the effective fusion of digital geological modeling, actual grouting process and tunnel risk evaluation lacks in-depth research. Existing research methods often adopt generalized treatment for grouting simulation considering actual projects, and cannot accurately simulate the grouting effect of actual projects.

### SUMMARY

In order to solve the above problems, the present invention provides a pre-control and monitoring method and system for a whole process of an actual grouting engineering based on digital geological model, and realizes real calculation of an actual underground engineering model and optimization of a grouting parameter solution, as well as pre-control and analysis of grouting data in actual engineering monitoring through digitized characterization of a underground geologic body structure model.

According to some examples, the present invention adopts the following technical solutions.

A pre-control and monitoring method for a whole process of an actual grouting engineering based on digital geological model, including:
acquiring images of a tunnel face, performing image enhancement processing on the obtained images of the tunnel face, and extracting structure features of the tunnel face based on the enhanced images of the tunnel face;
laying sensors according to the extracted structure features of the tunnel face; wherein, the sensors comprise an acoustic signal sensor and nanosensors, wherein the acoustic signal sensor is fixed on the tunnel face and continuously monitor changes of a diffusion range of a grouting slurry in a grouting project;
carrying out underground drilling on a stratum within a range of a section to be excavated, obtaining underground borehole data and geological logging data, extracting and meshing fracture surfaces in the stratum, calculating fractal dimension of the fracture surfaces, inspecting a coplanarity of discontinuous fracture surfaces, and building an underground geologic body structure model;
extracting multi-source attribute data values from images of surrounding rocks and the underground borehole data, dividing the underground geologic body structure model into spatial grid units, assigning the multi-source attribute data values to the underground geologic body structure model, to obtain a multi-source geologic body attribute model;
building an underground engineering risk-assessment model to perform multi-factor disaster risk region assessment for each of the spatial grid units, to achieve a prediction of a high-risk region for geological disaster;
carrying out a grouting simulation for the high-risk region for geological disaster, and optimizing and solving the grouting simulation by using multiphase flow calculation method, obtaining optimized physical values of grouting parameters of grouting in the high-risk region for geological disaster;
controlling grouting equipment according to the optimized physical values of the grouting parameters, to perform an actual grouting engineering on the predicted high-risk region for geological disaster;
injecting the grouting slurry mixed with the nanosensors based on regional characteristics of the high-risk region for geological disaster into the section to be excavated, marking the nanosensors by using fluorescent substances; detecting fluorescent signals of the nanosensors by using fluorescence imaging technology after the nanosensors entering the section to be excavated; obtaining diffusion range of the grouting slurry data in the actual grouting engineering by accurately tracking positions of the nanosensors in the grouting slurry by monitoring the fluorescent substances, and obtaining the diffusion range data of the grouting slurry in the actual grouting engineering;
adjusting the physical values of the grouting parameters in the grouting simulation and the multi-source geologic body attribute model by using a control variable method and based on the obtained diffusion range data of the grouting slurry, to obtain a multi-factor diffusion range with variable coefficients in the actual grouting engineering; learning and capturing a complex mapping relationship between different parameters by using a neural network, to monitor and optimize a whole process of the actual grouting engineering in real-time; and
controlling the grouting equipment according to the real-time adjusted and optimized physical values of the grouting parameters, to complete the whole process of the actual grouting engineering.

According to some examples, the present invention adopts the following technical solutions.

A pre-control and monitoring system for a whole process of an actual grouting engineering based on digital geological model, including:
a data acquisition module, configured to obtain underground borehole data and geological logging data;
an underground geologic body structure modeling module, configured to extract and mesh fracture surfaces in a stratum, calculate fractal dimension of the fracture surfaces, inspect a coplanarity of discontinuous fracture surfaces, and build a underground geologic body structure model;
a multi-source geologic body attribute modeling module, configured to extract multi-source attribute data values from images of surrounding rocks and the underground borehole data, divide the underground geologic body structure model into spatial grid units, assign the multi-source attribute data values to the underground geologic body structure model, to obtain a multi-source geologic body attribute model;
a tunnel risk assessment module, configured to build a underground engineering risk-assessment model to perform multi-factor disaster risk region assessment for each of the spatial grid units, to achieve a prediction of a high-risk region for geological disaster;
a grouting simulation module, configured to optimize and solve a grouting simulation for the high-risk region for geological disaster by using multiphase flow calculation method;
a multimodal grouting analysis module, configured to adjust the physical values of the grouting parameters by using a control variable method and based on the obtained diffusion range data of the grouting slurry, obtain a multi-factor diffusion range with variable coefficients in an actual grouting engineering; learn and capture a complex mapping relationship between different parameters by using a neural network, to monitor and optimize a whole process of the actual grouting engineering in real-time; and
an actual engineering control module, configured to control grouting equipment according to the optimized physical values of the grouting parameters obtained from the grouting simulation, to perform the actual grouting engineering on the predicted high-risk region for geological disaster; and configured to control the grouting equipment according to the real-time adjusted and optimized physical values of the grouting parameters, to complete the whole process of the actual grouting engineering.

According to some examples, the present invention adopts the following technical solutions.

A terminal device, comprising a processor and a memory storing a plurality of instructions that, when executed by the processor, causes the processor to perform a pre-control and monitoring method for a whole process of an actual grouting engineering based on digital geological model.

According to some examples, the present invention adopts the following technical solutions.

A non-transitory computer-readable storage medium, storing a plurality of instructions that, when executed by a processor of a terminal device, causes the processor to perform a pre-control and monitoring method for a whole process of an actual grouting engineering based on digital geological model.

Compared with the prior art, the beneficial effects of the present invention are as follows:

According to the present invention, the pre-control and monitoring method for the whole process of the actual grouting engineering based on digital geological model, builds a highly accurate 3D dynamic geological mode by fully utilizing multi-layer and multi-attribute data of geology, drilling, geophysical prospecting and the like, realizes comprehensive evaluation and 3D visual modeling of underground engineering risks. In the present invention, the stratum and discontinuous fracture surfaces are regarded as key elements of building the geologic bodies, and intelligent simulation of grouting process is realized by integrating multi-source attributes as boundary conditions, which provides more accurate geological information for underground engineering and scientific basis for decision-making in grouting process.

According to the present invention, the pre-control and monitoring method for the whole process of the actual grouting engineering based on digital geological model not only improves the efficiency of the grouting process, but also reduces the engineering risk, and provides powerful support for engineering decision-making; meanwhile, the system also has an intuitive 3D visualization function, so that engineers can understand underground conditions more comprehensively, a brand-new and more intelligent solution is provided for underground engineering, and the development and application of grouting technology are promoted.

### BRIEF DESCRIPTION OF THE DRAWINGS

The accompanying drawings constituting a part of the present invention are used to provide a further understanding of the present invention. The exemplary examples of the present invention and descriptions thereof are used to explain the present invention, and do not constitute an improper limitation of the present invention.

FIG. 1 is a flowchart of a method according to an example of the present invention;

FIG. 2 is diagram of a digital geological model risk assessment process according to an example of the present invention;

FIG. 3 is a schematic diagram of a diffusion form in grouting simulation according to an example of the present invention;

FIG. 4 is a structural diagram of a sensor fixing and conveying device according to an example of the present invention;

FIG. 5 is a structural diagram of a telescopic meshing tooth according to an example of the present invention; and

FIG. 6 is a schematic diagram of a sensor layout according to an example of the present invention.

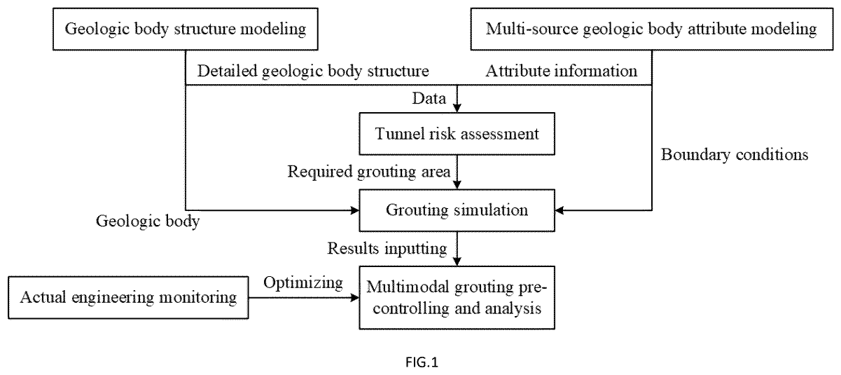

### DETAILED DESCRIPTION

The present invention will now be further described with reference to the accompanying drawings and examples.

It should be pointed out that the following detailed descriptions are all illustrative and are intended to provide further descriptions of the present invention. Unless otherwise specified, all technical and scientific terms used in the present invention have the same meanings as those usually understood by a person of ordinary skill in the art to which the present invention belongs.

It should be noted that the terms used herein are merely used for describing specific implementations, and are not intended to limit exemplary implementations of the present invention. As used herein, the singular form is also intended to include the plural form unless the context clearly dictates otherwise. In addition, it should further be understood that, terms “include” and/or “including” used in this specification indicate that there are features, steps, operations, devices, components, and/or combinations thereof.

### Example 1

An example of the present invention provides a pre-control and monitoring method for a whole process of an actual grouting engineering based on digital geological model, including:
step one: obtaining underground borehole data and geological logging data, extracting and meshing fracture surfaces in a stratum, calculating fractal dimension of the fracture surfaces, inspecting a coplanarity of discontinuous fracture surfaces, and building a underground geologic body structure model;
step two: extracting multi-source attribute data values from images of surrounding rocks and the underground borehole data, dividing the underground geologic body structure model into spatial grid units, assigning the multi-source attribute data values to the underground geologic body structure model, to obtain a multi-source geologic body attribute model;
step three: building an underground engineering risk-assessment model to perform multi-factor disaster risk region assessment for each of the spatial grid units, to achieve a prediction of a high-risk region for geological disaster;
step four: optimizing and solving a grouting simulation for the high-risk region for geological disaster by using multiphase flow calculation method, and obtaining optimized physical values of grouting parameters of grouting in the high-risk region for geological disaster for controlling grouting equipment to perform an actual grouting engineering on the predicted high-risk region for geological disaster; adjusting the physical values of the grouting parameters by using a control variable method and based on the obtained diffusion range data of the grouting slurry, obtaining a multi-factor diffusion range with variable coefficients in the actual grouting engineering, and pre-controlling and monitoring a whole process of the actual grouting engineering by learning and capturing a complex mapping relationship between different parameters by using a neural network; wherein,
controlling the grouting equipment to complete the whole process of the actual grouting engineering according to the adjusted and optimized physical values of the grouting parameters output in real-time.

As an example, the pre-control and monitoring method for the whole process of the actual grouting engineering based on digital geological model disclosed by the present invention, comprises the following steps of: building an underground geologic body structure model, and assigning various attribute data values to the underground geologic body structure model, to obtain a multi-source geologic body attribute model; then, dividing spatial grid units for the multi-source geologic body attribute model, predicting risk regions, performing a grouting simulation for a high-risk region, and performing an actual grouting, wherein, continuously optimizing physical values of grouting parameters according to actual grouting parameter data, to pre-controlling a whole process of the actual grouting. Specifically, a specific implementation process of the solution mentioned above, including:

Step 1: building the underground geologic body structure model based on the borehole data and stratigraphic profiles in the geological logging data.

1) Firstly, in terms of processing the borehole data, transforming discrete borehole data into continuous subsurface rock and soil models by using efficient data processing techniques, through integration of key parameters such as core analysis, formation thickness and pore structure, and using interpolation methods (such as Kriging interpolation).

A process of processing the geological logging data includes depth analysis and image generation. By using image processing technology and geographic information system (GIS) technology, deep analyzing rock character, structural characteristics and stratigraphic changes and like in the geological logging data, to generate a stratigraphic profile map.

In a modeling stage of the underground geologic body structure model, advanced 3D modeling techniques such as volume element method or finite element method are used to accurately restore the underground structure. By analyzing the geometry, pore structure and spatial distribution of geologic body, generating highly realistic stratum body structure by using interpolation method and numerical modeling method.

Wherein, the borehole data and geological logging data include geological exploration data, geophysical data, surrounding rock images, cognition data while drilling and in-situ test data, and processing of each method flow is carried out based on these data.

Further, the building of the underground geologic body structure model is based on: analyzing the discontinuity of the fractures through the borehole data, extracting the discontinuous fracture surfaces in the stratum, and calculating the fracture fractal dimension; which includes:
firstly, identifying borehole images based on machine vision technology, and then carrying out image processing and fractal dimension calculation, that is: based on the principle of fractal geometry, measuring the complexity of fracture surface by using the fractal dimension calculation method, such as Box Counting Method;
secondly, extracting fractal dimension data of discontinuous fracture surfaces and calculating the fractal dimension, inspecting a coplanarity for obtained each of the discontinuous fracture surfaces, assigning the calculated fractal dimension as a structural attribute value to the geologic body structure to complete the building of the underground geologic body structure model.

As an example, analyzing the discontinuity of fractures, extracting the fractal dimension data of the each of the discontinuous fracture surfaces, calculating fracture fractal dimension to obtain the each of the discontinuous fracture surfaces, and inspecting the coplanarity of the each of the discontinuous fracture surfaces, specifically including:

S101: identifying trace fractures by using an existing machine vision semantic segmentation model, includes: inputting obtained different borehole images and point cloud information into the machine vision semantic segmentation model, outputting the trace fractures, and fitting the trace fractures by using a disk model to obtain fracture fractal dimension data; wherein, the fracture fractal dimension data includes fracture plane inclination, dip angle, trace length, center coordinates, fracture plane number, and the like.

S102: using an existing rock mass fracture recognition model built by migration learning, inputting the borehole images to the rock mass fracture recognition model, outputting fractures in the borehole images, then calculating the fracture fractal dimension data, and obtaining discontinuous fracture surfaces inside the rock mass based on the calculated fracture fractal dimension data; wherein, in the present example, the rock mass fracture recognition model may be a relatively mature semantic segmentation model at present.

As an example, the identification of the trace fractures by using the machine vision semantic segmentation model, and the identification of the fractures by using the rock mass fracture recognition model, are both achievable by a person skilled in the art according to the prior art.

Further, the calculation of the fracture fractal dimension data, specifically includes:
(1) obtaining an inclination and a dip angle of a fracture by using a borehole position and a borehole radius of the fracture measured in situ;
(2) expanding a fracture plane in the borehole image of the fracture as a sine curve along a borehole edge, randomly extracting discrete points in the borehole image of the fracture, fitting a distance between the discrete points and a best-fitting plane by using a normal curve, and calculating a standard deviation σ of the normal distance from the discrete points to the best-fitting plane as a dispersion degree;

As an example, the best-fitting plane may be obtained by using MATLAB programming, specifically is: when all discrete points obtained by using the least squares method are minimum values to a certain plane, the plane is the best-fitting plane.
(3) taking a depth of the borehole where the fracture is located as a depth of the fracture plane, and characterizing the position of the fracture by a center coordinate of the fracture plane.

Furthermore, carrying out a coordinate unification for the fractal dimension data obtained from different boreholes. Because of the borehole has vertex angle and azimuth angle itself, the coordinate system of digital representation of each borehole fracture is different, so it is necessary to normalize the information through unified coordinates and scales, which is to unify the coordinates of structure plane into absolute coordinate system. The concrete coordinate conversion method is realized by adopting the prior art.

S103: as an example, discontinuous fracture surfaces of fractures of different boreholes have spatial correlation, and two discontinuous fracture surface regions of disconnected boreholes may be compatible with a same plane equation. By using the obtained discontinuous fracture surfaces of fracture fractal dimension data and performing coplanar inspection on different discontinuous fracture surfaces, to judge whether different discontinuous fracture surfaces belong to a same spatial plane dataset, so that the built underground geologic body structure model can be more practical, the comprehensiveness of model space construction can be considered, and the error between the built underground geologic body structure model and the actual geological structure can be reduced. For some subsequent models and fracture analysis, it is closer to the reality. Therefore, performing coplanar inspection on different discontinuous fracture surfaces, to judge whether different discontinuous fracture surfaces belong to the same spatial plane dataset, including:
converting the obtained fractal dimension data of fractures into digital attribute representations of different fracture surfaces to form a discontinuous dataset; and clustering the fracture surfaces in a discontinuous dataset to obtain a clustered dataset. By comparing the difference between the parameters of the best-fitting plane for the fracture surfaces and the standard deviation of the normal distance, inspecting the coplanarity of different fracture surfaces in the same cluster to obtain multiple common surface datasets; fitting all the center coordinates of the same coplanar dataset to a convex polygon ring as the edge of the discontinuous fracture surface, and extracting the convex polygon discontinuous fracture surface;
clustering the fracture surfaces in the discontinuous dataset specifically is: judging whether two fracture surfaces belong to the same cluster category according to the proximity of plane normal vectors of plane equations corresponding to each fracture surface, and dividing the same cluster according to the proximity;
for two fracture surfaces in the same cluster category, judging whether the two fracture surfaces are coplanar by comparing the difference between the parameters of the best-fitting plane of the fracture surface and the standard deviation of the normal distance, specifically is: letting “D1” and “D2” be the parameters of the best-fitting plane equation of the two fracture surfaces, letting “σ1” and “σ2” be the standard deviations of the normal distance from all discrete points of the two fracture surfaces to the best-fitting plane, and “k” is a parameter controlling sensitivity of the inspection; when the difference of the D values of the two fracture surfaces is less than the sum of standard deviations multiplied by a certain sensitivity parameter, the specific expression form is: D1−D2<k(σ1+σ2), then the two fracture surfaces belong to a coplanar dataset; and
after completing the coplanar inspection of the each of the discontinuous fracture surfaces, carrying out the analysis of the geologic body structure; wherein the geologic body structure includes homogeneous geologic bodies and unfavorable geologic bodies. The homogeneous geologic bodies and unfavorable geologic bodies in the geological exploration data and geophysical exploration data are obtained by using the existing fitting method. Embedding the unfavorable geologic bodies into the average geologic body structure, taking the result of whether each discontinuous fracture surface is coplanar as the geologic body structure attribute and assigning to the underground geologic body structure model, to complete the building of the underground geologic body structure model.

Step 2: building the multi-source geologic body attribute model.

Obtaining the underground geologic body structure model, dividing the underground geologic body structure model into spatial grid units, and building a unit-body 3D attribute data structure; the unit-body 3D attribute data structure comprises spatial information and attribute information, wherein the spatial information comprises unit-body 3D spatial coordinates, and the attribute information comprises water-content attribute, fracture-density attribute, element-content attribute, rock mass-strength attribute, crustal stress attribute, lithological distribution attribute and the like.

The underground geologic body structure model is divided into closely arranged space grid units (i.e., cubes of 3D unit-bodies with self-defined size, but the unit-bodies can be divided into irregular cubes by boundary constraints at special positions such as field boundary and stratum boundary to better adapt to the model structure; the unit-body size can be set by integrating the overall geological model size and attribute density of the site), and the center of each of the unit-bodies is a point, which is called geological point. Then using these geological points to build a geological point attribute data structure, and storing each unfavorable geological point as an attribute in the geological points. For the obtained multi-attribute geologic body models, the attribute distribution states can be viewed separately, and different attributes can be assigned different weight values according to the importance according to the engineering needs, so as to obtain a geological attribute fusion model. Before building the geological attribute fusion model, it is necessary to normalize each attribute data, that is, eliminating the dimensional difference between various attribute values and mapping them to the dimensionless interval [0, 1] (that is, when the unit body is located in unfavorable geologic bodies such as water-rich stratum, karst and fault, the attribute of the unit body is assigned to 1). The geological attribute fusion model can simultaneously reflect the comprehensive influence of different attributes on geological field regions, which has certain engineering significance.

Further, obtaining multiple multi-source attribute information based on the surrounding rock images, the cognition data while drilling and the in-situ test data, and based on the information of the surrounding rock images, the cognition data while drilling and the in-situ test data, identifying fractures, rock character distribution and fracture regions in the surrounding rock images by using a convolutional neural network model; according to the discreteness of the data, simulating and obtaining unit-body 3D attribute information values of a whole to-be-tested region; and, analyzing the multi-source attribute information to judge whether the multi-source attribute information is continuous data or not, and obtaining the multi-source attribute data value by using different simulation methods according to the judgment result.

Specifically, based on the surrounding rock images, cognition data while drilling and in-situ test data, obtaining the fracture attitude information, rock mass integrity characteristics and lithological distribution characteristics in the surrounding rock images, the geochemical characteristics, mechanical parameters and physical parameters in the cognition data while drilling data, and water inflow and in-situ stress data in the in-situ test. Then, judging whether these obtained data above are continuous data or not, by using a kernel density estimation method to estimate the smooth of the distribution of the data, wherein the kernel density estimates for continuous data usually present smooth curves, while discrete data may present distinct peaks. Therefore, whether the data are continuous data or not is judged according to this, wherein if yes, attribute data values are obtained by using a sequential Gaussian simulation method; if not, attribute data values are obtained by using a sequential indication simulation method. And, assigning the obtained attribute data values to the unit-body 3D attribute data structure to obtain the multi-source geologic body attribute model.

Step 3: building the underground engineering risk-assessment model to predict high-risk disaster regions.

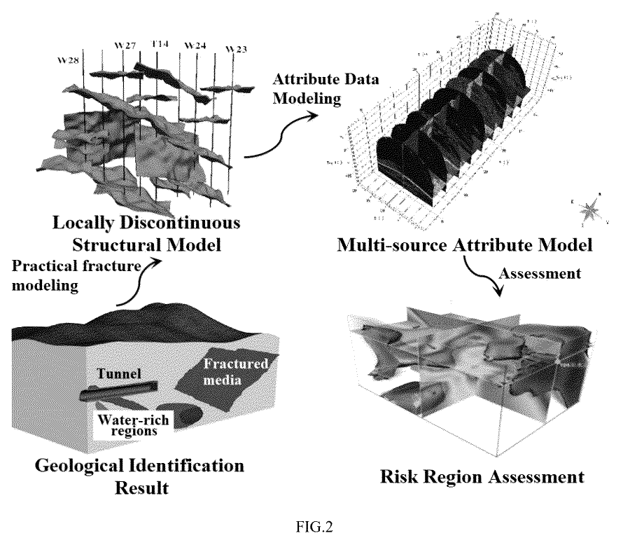

As an example, the underground engineering risk-assessment model is built based on the multi-source geologic body attribute model divided into a plurality of spatial grid units (3D unit bodies), as shown in FIG. 2, and multi-factor disaster risk region assessment is performed on each of the spatial grid units to predict disaster high-risk regions;
specifically, building the underground engineering risk-assessment model based on actual stored data of grouting engineering, and carrying out the multi-factor disaster risk region assessment on the each of the spatial grid units, including: a surrounding rock grade assessment, a crustal stress assessment, a water and mud inrush assessment and a grouting region assessment; then predicting the disaster high-risk regions, and carrying out the grouting simulation on the predicted disaster high-risk regions.

Further, the prediction of the disaster high-risk regions, including:
based on grouting engineering database, determining the underground engineering risk-assessment regions according to the plurality of divided space grid units, wherein each of the divided space grid units is a cube with a set size, and each the cube has a center point;
the underground engineering risk-assessment model takes divided space grid units as basic units, and takes data in the units as characterization data of the whole units;
wherein, the underground engineering risk-assessment model includes the surrounding rock grade-assessment model, the crustal stress-assessment model, water and mud inrush-assessment model, grouting region-assessment model.

Firstly, identifying fracture images by existing semantic segmentation model, to obtain the fracture fractal dimension data, storing the fractures in an array by fracture vectorization (a characterization method of fractal dimension data of fractures), extracting pixel coordinates of the fracture storage array and recording as a two-dimensional (2D) array SLD [i][j] (i is a fracture number, j is a fracture composition point number. D(i) is a length of each differential fracture), obtaining the length and width of a single fracture by calculating by using differential method, calculate by cyclic function, obtaining a distance between adjacent pixel points of each differential, and carrying out a coordinate conversion according to a ratio between the picture size and the actual shooting size; then, accumulating the length of each differential fracture unit to obtain a total length l and a total width w of the single fracture, so as to obtain the fracture distribution information including the fracture density and length; and then, evaluating the fracture density of data of the each grid unit, wherein dividing fracture density into different grades, such as low density, medium density, high density, etc., then according to the total weighted length and fracture density attributes of fractures, evaluating stability of the grid units by using existing methods, and then classifying the each grid unit into different grades, e.g. stable, slightly unstable, moderately unstable, severely unstable, etc.

Groundwater content assessment: using level information of groundwater table, and combining with existing machine vision data, to assess the impact of groundwater content on surrounding rock. Wherein, according to the level of groundwater table, the groundwater content is divided into different grades, such as low, medium and high grades. And, a stability grade of the grid unit is adjusted, by combining with the evaluation of stability of the surrounding rock, and considering the possibility of groundwater to fracture propagation and soil loss.

Rock character evaluation: obtaining information of rock character by using existing machine vision, and/which the information includes rock strength and stability. According to the strength and stability of the rock, dividing the rock character into different grades, such as hard, medium and soft grades. Combining the grade of rock character with fracture distribution and groundwater content to adjust the stability grade of the grid unit.

Unfavorable geologic body-scale assessment: obtaining information on the scale of unfavorable geologic bodies by using existing machine vision, and/which the information includes volume, diffusion range, etc. According to the scales of the unfavorable geologic bodies, dividing the unfavorable geologic bodies into different grades, such as: small-scale grade, medium-scale grade, and large scale grade. Adjusting the stability grade of the grid unit by considering the potential influence of unfavorable geologic bodies on the stability of the surrounding rock.

Fractured degree evaluation: obtaining information on the degree of fragmentation by using existing machine vision, and/which the information includes a degree of rock fracture, fragment size, etc. According to the fractured degree, classifying rocks into different grades, such as complete, slightly fractured, moderately fractured and severely fractured grades. Adjusting the stability grade of the grid unit by combining the information of fractured degree, fracture distribution and groundwater content.

Comprehensive evaluation and grade adjustment: comprehensively considering the evaluation results of the above factors to determine the grade of the surrounding rock of the each grid unit. Based on an overall risk assessment criterion, assigning a corresponding risk value to each level. Adjusting the grade to ensure that the weight of each factor is reasonably balanced, so as to obtain the final evaluation result of grade of surrounding rock.

Water and mud inrush assessment: obtaining a spatio-temporal distribution of the level of the groundwater table by using monitoring data of the level of groundwater table; combined with the underground geologic body structure model, simulating groundwater flow path, to determine the region that may affect the stability of the surrounding rock; calculating the groundwater flow in different regions to obtain distribution information of the groundwater flow.

As an example, the stability classification and adjustment of the grid units in the underground engineering risk-assessment model can be realized by using existing methods.

Finally, the region with low stability of surrounding rock and high risk of water and mud inrush is determined as the high-risk region for geological disaster, to carry out the grouting simulation.

Step 4: Grouting simulation.

As an example, the grouting simulation is performed by using a grouting simulation system, takes the underground geologic body structure model as the geologic body structure, and uses multi-source attribute information as boundary conditions, to initialize settings of the grouting simulation, wherein the settings include boundary conditions, grouting speed, grouting pressure, dynamic water initial flow field, diffusion form of grouting slurry, viscosity of grouting slurry, spatial distribution data, etc., and to initialize geological parameters that include formation type, rock character, permeability, porosity, aquifer condition, fracture region, rock mass strength, crustal stress, etc.; gridding the disaster high-risk region through calculation, setting a size of the grid to be an integer multiple of the size of the unit body, and maintaining a relationship between the number of grids and calculation nodes of server to be that each set number of the grids corresponds to one calculation node, so that required calculation nodes may be determined according to the number of the grid.

In the grouting simulation, specifically includes, solving the grouting simulation by using multiphase flow calculation method, and a specific process is as follows:

1) Establishing momentum equations and continuity equations:

$$\frac{\partial ( {α}_{i} {ρ}_{i} {U}_{i} )}{\partial t} + ∇ \cdot ( {α}_{i} {ρ}_{i} {U}_{i} ) - ∇ \cdot ( {α}_{i} {ρ}_{i} {τ}_{i} ) = - {α}_{i} ∇ {p}_{i} + {α}_{i} {ρ}_{i} g + M , \frac{\partial ( {α}_{i} {ρ}_{i} )}{\partial t} + ∇ \cdot ( {α}_{i} {ρ}_{i} {U}_{i} ) = 0 ,$$

where, subscript i represents different phases, for two-phase flow, i can be divided into two phases: s representing the grouting slurry and w representing the water, respectively; α represents phase fraction, ρ represents density, U represents velocity, p represents pressure, g represents gravity vector, and t represents effective stress and can be expressed as:

$${τ}_{i} = - {v}_{i} ( ∇ {U}_{i} + {∇}^{T} {U}_{i} ) + \frac{2}{3} {v}_{i} ∇ \cdot ( {U}_{i} \cdot I ) ,$$

where, v is the molecular kinematic viscosity, I is the unit matrix, and T is time.

Further, M is an interfacial exchange force and can be expressed as:

$$M = {M}_{d} + {M}_{l} + {M}_{v} + {M}_{w} + {M}_{t} ,$$

where, M_{d} is axial drag force, Mₗ is radial force, Mᵥ is virtual mass force, M_{w} is wall lubrication force and Mₜ is turbulent dispersion force.

2) Describing a viscosity change of the grouting slurry in grouting process and building a calculation model of transmission time:

$$\frac{\partial {T}_{s}}{\partial t} + ∇ \cdot [ ( {α}_{s} {U}_{s} + {α}_{w} {U}_{w} ) {T}_{s} ] = {α}_{s} ,$$

where, T is the time term.

3) Establishing boundary conditions. The boundary conditions can be set as the change of velocity and pressure. Taking the level of groundwater table obtained from the underground geologic body structure model module as the boundary condition of inflow and outflow. Changing the position, size, shape and quantity of grouting inlet of the calculation model to achieve the effect of different grouting methods such as compaction grouting and curtain grouting, and simulating the diffusion of grouting slurry under different construction technology conditions. Simulating the diffusion of the grouting slurry under space-time dual-variable conditions for different slurry types according to time-varying function of slurry increasing-different viscosity. Wherein, the diffusion form is described by using three coordinate directions and eight quadrant diagonal directions in a 3D coordinate system, as shown in FIG. 3, and the diffusion range is comprehensively characterized by using the diffusion distance of slurry in fourteen directions shown in the figure. And, conducting sectional grouting simulation of the calculation model, and setting other parameters of grouting in each section.

4) Simulating and calculating different grouting parameter combinations by using a numerical simulation, generating training samples by changing grouting parameters in the grouting simulation system and different attribute values (such as fracture density, water inflow, mineral content, etc.) in the multi-source attribute geological model, wherein keeping one grouting parameter changing in different parameter combinations, and other grouting parameters unchanged.

The grouting effect achieved by numerical simulation can be expressed as:

$${A}_{i} = \frac{{S}_{i}}{{T}_{i}} , i = 1 , … , N$$

where, Aᵢ represents grouting effect value achieved by i^{th} numerical simulation grouting solution, Sᵢ represents diffusion range of grouting slurry and Tᵢ represents grouting sealing time.

According to an effect value of one grouting effect, calculating an optimal addition value of each of the grouting parameters to the grouting effect, which can be expressed as solving a matrix equation:

$${B ( s )}_{i , j} = k {A}_{i} , i = 1 , … , M , j = 1 , … , N$$

where, B(s)_{i,j} is an optimized bonus matrix of the j^{th} grouting parameter in the i^{th} numerical simulation grouting solution, k is the loss coefficient matrix converted from the grouting effect value to the optimized bonus value, and Aᵢ is the grouting effect score matrix of the i^{th} numerical simulation grouting solution, wherein M≥N.

5) Solving the matrix equation above by selecting a plurality of groups of numerical simulation grouting solution data to obtain optimized bonus values of the plurality of groups of grouting parameters, and calculating the final optimized bonus values of the grouting parameters by averaging the optimized bonus values of the plurality of groups of grouting parameters.

6) Optimizing the grouting solution on the basis of existing numerical simulation grouting solution data by using particle swarm optimization algorithm, wherein each simulated grouting solution parameter is regarded as particle as initialization data, and attached attributes thereof are current grouting parameter configuration and achieved grouting effect, and the iterative calculation formula is expressed as follows:

$${A}_{i}^{k + 1} = ω {A}_{i}^{k} + {c}_{1} \times rand ( ) \times ( p {b}_{i , j}^{k} - {s}_{i , j}^{k} ) + {c}_{2} \times rand ( ) \times ( g {b}_{i , j}^{k} - {s}_{i , j}^{k} ) ,$$

where, Aᵢ represents the grouting effect value achieved by the i^{th} numerical simulation grouting solution, w represents the inertia factor (which can be dynamically adjusted according to different calculation models), c₁ and c₂ are the learning factors, rand( ) is the random function, pb_{i,j} is a historical optimal solution of the particle itself, and gb_{i,j} is a group optimal solution, s_{i,j}={s_{i,1}, s_{i,2}, . . . , s_{i,N}}, i=1, 2, . . . , m represents the parameter vector of the particle, the right superscript of each parameter represents the number of iteration steps. In addition, an iteration mode of grouting parameter configuration is:

$${s}_{i , j}^{k + 1} = {s}_{i , j}^{k} + rand ( ) \times ( g {b}_{i , j}^{k} - g {b}_{i , j}^{k - 1} ) + {A}_{i}^{k + 1} ,$$

where, the right superscript of each parameter represents the number of iteration steps.

In the above two iterative calculation processes, an interval range of each parameter vector in the s_{i,j} should be set, and the calculation space in which it exists should be specified, that is, s_{i,j}ϵ[a₁, a₂].

Setting the iterative steps to loop the iterative calculations until the final step outputs the overall optimal solution.

Step 5: Obtaining optimized physical values of the grouting parameters, and controlling grouting equipment to perform the actual grouting engineering on the predicted high-risk region for geological disaster according to the optimized physical values of the grouting parameters; meanwhile, based on the obtained diffusion range data of the grouting slurry, adjusting the physical values of the grouting parameters by using a control variable method, to obtain a multi-factor diffusion range with variable coefficients in the actual grouting engineering, learning and capturing complex mapping relations among different parameters by using a neural network, and performing pre-controlling, monitoring and optimization of the whole process of an actual grouting engineering in real-time; and, controlling the grouting equipment according to the real-time adjusted and optimized physical values of the grouting parameters, to complete the whole process of the actual grouting engineering.

Wherein, a method for obtaining actual grouting engineering data is as follows: the data is obtained in a manner of monitoring under an optimal sensor layout mode, which mainly is a mixed layout monitoring of an acoustic signal sensor and the nanosensors, wherein the acoustic signal sensor is laid on the tunnel face according to the structural characteristics of the tunnel face, and used to continuously detect the diffusion range of the grouting slurry change in the grouting process; the nanosensors are transported to the section to be excavated in different ways in different regions, marking the nanosensors by fluorescent substances; after the nanosensors enters, accurately tracking the position of the nanosensors by detecting fluorescence signals and monitoring the fluorescent substances by using fluorescence imaging technology, to obtain grouting pressure, grouting speed and diffusion range data.

Specifically, in the grouting process of the tunnel, the acoustic signal sensor laid on the tunnel face play an overall monitoring role and monitor the diffusion range of the grouting slurry in the grouting process in real time; the nanosensors laid in the section to be excavated play a local fine monitoring role and mainly obtain data such as grouting pressure, grouting rate and diffusion range. The specific optimization process of the layout mode of the acoustic signal sensor and the nanosensors disclosed in the present invention is as follows:

(1) Obtaining structural characteristics of the tunnel face.

In the present example, collecting images of the tunnel face using a high-precision camera, sharpening the images and extracting structural features of the tunnel face in the images.

(2) Laying the acoustic signal sensor based on the structural characteristics of the tunnel face.

In the present example, the acoustic signal sensor is laid according to the structural characteristics of the tunnel face, for example, the layout density of the sensors is planned according to the fracture density, geotechnical properties, deformation conditions and other factors of the tunnel face. For regions with dense fractures, it may be necessary to increase the layout density of sensors, i.e., the number of sensors per unit region increases, thereby increasing the accuracy of monitoring results.

In the present example, the layout mode of the sensors, such as triangle, rectangle, ring, etc., is considered according to the characteristics such as the size and shape of the tunnel face, the layout density of the sensors is determined according to the actual situation after selecting the mode, and the acoustic signal sensor is fixed on the tunnel face by a fixing device.

(3) Laying the nanosensors based on a construction of exploration hole (borehole) of grouting.

In the construction of exploration hole, injecting a probe and a contrast agent into the hole in real time by using a drilling rotary jet method, wherein the probe is use for emitting acoustic signals to the surroundings, and the contrast agent is use for enhancing the transmission benefit of the acoustic signals; and the principle is that the contrast agent contains tiny gas micro-bubbles, and the existence of the gas micro-bubbles can cause acoustic impedance discontinuity in the transmission of the acoustic signals, so that the reflection and scattering of the acoustic signals are enhanced, and the acoustic signal sensor on the tunnel face accurately receives the acoustic signals.

In the present example, water-rich characteristics are judged according to whether there is water inrush phenomenon in the field construction, and if there is water inrush, it is judged as a water-rich region, and the nanosensors can be directly mixed into the grouting slurry and injected into the section to be excavated together with the grouting slurry.

Otherwise, it is judged as non-water-rich region. When acoustic signal passes through broken rock mass and intact rock mass, the wave image of acoustic signal formed is different. By collecting amplitude, frequency, duration and other information of field acoustic signal waveform diagram, it can be judged whether there are structural characteristics such as fracture or fracture region in the non-water-rich region. If there are structural features such as fractures or fracture regions in the region, the nanosensors are transported to the fractures or fracture regions by a conveying device to achieve a targeted layout effect; if the structure in the region is intact and there are no fractures and other features, no treatment is performed.

In the present example, the acoustic signal sensor plays an overall monitoring role, which is used to monitor the diffusion of the grouting slurry in the grouting process in real time; at the same time, the acoustic signal sensor may obtain the information of the acoustic signal and determine whether there is a fracture or a fracture region in the section to be excavated based on the acoustic signal.

The nanosensors plays a role of local refinement monitoring and is used for monitoring pressure and flow velocity of the internal grouting slurry in the grouting process, so as to make up for the deficiency that the acoustic signal sensor cannot accurately obtain real-time data of the internal grouting slurry due to obstruction of rocks, and fluorescent substances are used for marking, so that the real-time position of the nanosensors can be effectively tracked, and the diffusion range of the grouting slurry can be further obtained; when the section to be excavated is a water-rich region, the grouting slurry which nanosensors are mixed is injected to the section, so the nanosensors are sent into the section; when the section to be excavated is a non-water-rich region and a fracture or fracture region exists, the nanosensors are sent into the fracture or fracture region. According to the monitoring data of the acoustic signal sensor and the nanosensors, grouting effect can be directly reflected, and then tunnel construction can be guided efficiently and safely.

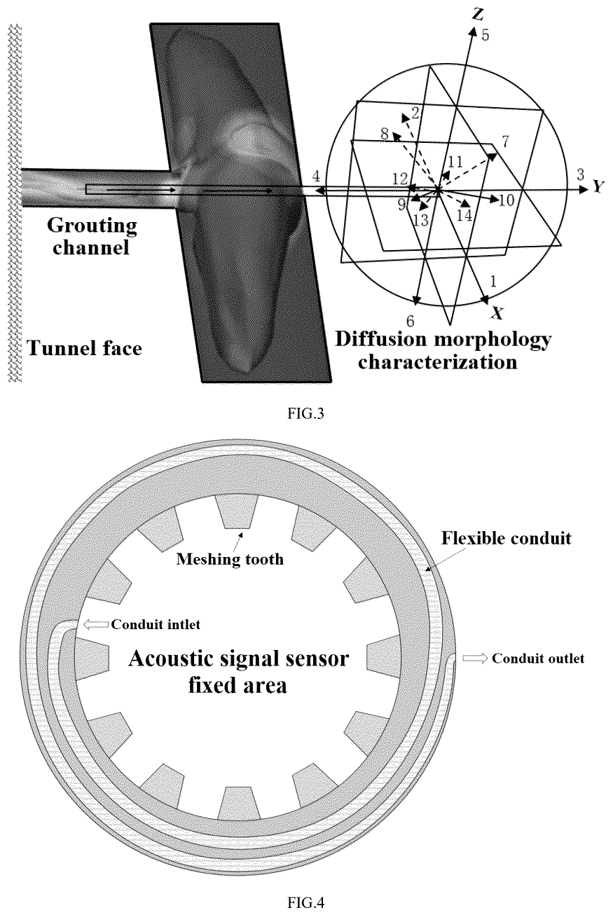

In the present example, the nanosensors are sent into the section to be excavated with structural characteristics such as fractures or fracture regions through a sensor-fixing and conveying device. Referring to FIG. 4, the sensor-fixing and conveying device comprises a circular hollow base, and the hollow base is fixed on the surface of the tunnel face through a vacuum chuck; the vacuum chuck is of epoxy resin with adhesive force, because the epoxy resin has good adhesion, which can ensure that the chuck is firmly adhered to the surface of rock mass.

A flexible conduit with sufficient length is surrounded in an inner space of the hollow base, an inlet of the flexible conduit is taken as a front end, and an outlet is taken as a tail end; the tail end of the flexible conduit can be drawn out of the hollow base and extended into the set position of the fracture in the borehole, and the surface of the flexible conduit is marked with a scale so as to facilitate determination of the depth position.

In the present example, referring to FIG. 5, the acoustic signal sensor is fixed in an acoustic signal sensor fixing region at a central position of the hollow base, a plurality of telescopically adjustable meshing teeth are uniformly arranged on a hollow wall of an inner space of the hollow base in a circumferential direction, bayonet or groove is arranged at an end of the meshing teeth, and after all the meshing teeth extend out, the acoustic signal sensor can be firmly fixed together through the bayonet or groove. The acoustic signal sensor may play a overall monitoring role, mainly to obtain diffusion range of the grouting slurry and other data.

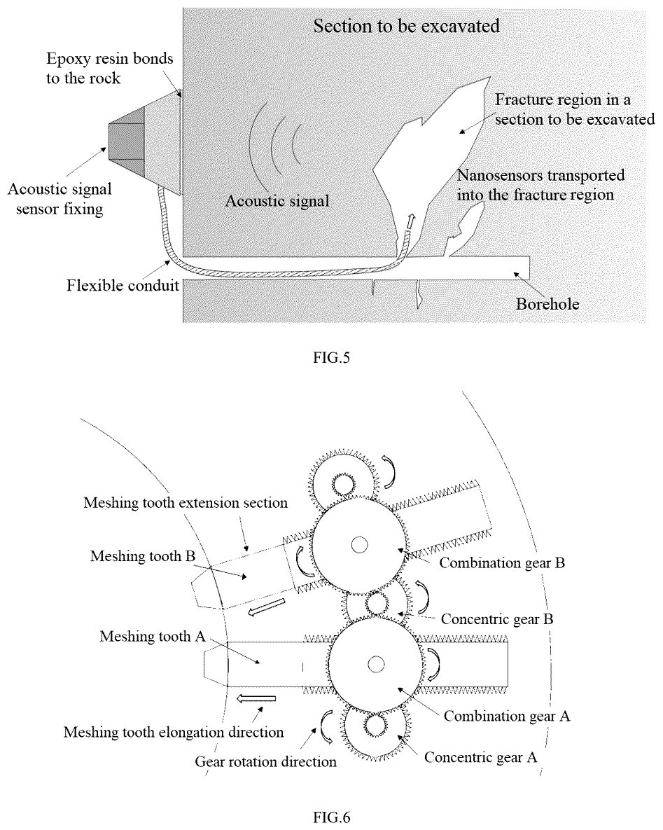

FIG. 6 shows a detailed structure of telescopically adjustable meshing teeth, including several concentric gears, several coupling gears, telescopically meshing tooth cylinders, and bolts coaxial with the starting gear (concentric gear). Wherein the coupling gear meshes with the inner gear of the adjacent concentric gear, and the meshing tooth cylinders mesh with an outer gear of the adjacent concentric gears.

Specifically, racks are provided on both sides of each meshing tooth, and concentric gears are provided between two adjacent meshing teeth. The concentric gears include a first gear (external gear) and a second gear (internal gear) that rotate coaxially; the first gear (external gear) is engaged with the racks of the meshing teeth on both sides thereof, and the second gears (internal gears) of two adjacent concentric gears are respectively engaged with the same coupling gear.

The bolt (coaxial with concentric gear A) is a driving element. The concentric gear A can be controlled to rotate by twisting the bolt, the external gear of the concentric gear A can drive meshing gear A to advance or retract; at the same time, the internal gear of the concentric gear A can drive coupling gear A to rotate, the rotation of the coupling gear A can drive concentric gear B to rotate, the external gear of the concentric gear B can drive meshing gear B to advance or retract, the internal gear of the concentric gear B can drive coupling gear B to rotate, and so on, to realize a synchronous advance or retraction of all meshing teeth.

According to the nanosensors of the present example, firstly, fluorescent markers are adsorbed on the surface of the nanosensors by electrostatic adsorption to mark the nanosensors; the nanosensors play a role of local refinement monitoring and mainly acquire information such as pressure, flow velocity and diffusion range of slurry in a grouting process; size of the nanosensors is small enough to enter the fracture region and the water-rich channel. During the grouting process, the grouting slurry will fill the channel. The position of the nanosensors can be accurately monitored by monitoring fluorescent substance, and the diffusion range information of the grouting can be further obtained to ensure accuracy.

The nanosensors are placed from the front end of the flexible conduit (the inlet end of the conduit), and then an air compressor pump is inserted at the front end of the conduit to generate an air flow that pushes the nanosensors to the end of the flexible conduit (the outlet end of the conduit) and into the fracture or fracture region.

During layout process, sticking the device on a selected point through epoxy resin suction cup, then placing the acoustic signal sensor in the central region, making the signal receiving ends of the sensors close to the rock wall, then adjusting the meshing teeth to the appropriate size to firmly fix the acoustic signal sensor; connecting the acoustic signal sensor to the data acquisition equipment or monitoring system, and calibrating and testing the sensor to confirm that the sensor can accurately capture and transmit acoustic signals; then, starting the acoustic signal sensor and carrying out the data acquisition.

In combination with that characteristic of the acoustic signal, determining the depth size of the fracture or fracture region in the borehole in the section to be excavate, extracting a flexible conduit from one end of the conduit outlet of the device and inserting the flexible conduit into the borehole, continuously adjusting according to the scale on the surface of the conduit, and finally ensuring that the opening of the conduit reaches the fracture or fracture region; putting a plurality of nanosensors into the inlet of the conduit at another end of the device, and then generating airflow in the conduit by using a nano air compression pump to push and convey the nanosensors into the fracture region. Tracking the position of the nanosensors using fluorescence imaging technology, wherein starting an image display equipment, exciting the fluorescent marker with an appropriate wavelength, capturing the emitted fluorescent signal, recording the movement track and position change of the nanosensors, and ensuring that it is accurately placed in the fracture region, providing guarantee for the accuracy of subsequent data acquisition. After grouting construction begins, collecting and monitoring the data of nanosensors.

(4) Continuous construction, processing and integrating the data collected by the acoustic signal sensor and the nanosensors.

In the present example, performing feature extraction and processing on the data received by the acoustic signal sensor, including: preprocessing the collected acoustic signals, including removing noise, filtering and amplifying the signal, performing time domain analysis on the preprocessed signal, and observing information such as amplitude, frequency and duration of sound through a waveform diagram. Fourier transform technology is used to transform time domain signal into frequency domain signal for frequency domain analysis, which can identify specific frequency acoustic signal and extract spectrum characteristics, and then visually display the generated image of the diffusion range of the grouting slurry, so as to intuitively understand the characteristics of acoustic signal.

In the present example, obtaining the grouting real-time pressure, velocity and diffusion range by data of monitoring the nanosensors, and storing the data in digital form to form continuous monitoring data for subsequent analysis. Wherein, fusing the diffusion range data and the image of the diffusion range of the grouting slurry to form integrated analysis display of digital map and improve accuracy. Grouting data such as real-time pressure and velocity are integrated into grouting database, and the Digital Twin model built based on the database may simulate the state change in grouting process. It is helpful to predict the influence of grouting on surrounding rock and find potential problems in advance. In addition, the Digital Twin model is used to optimize grouting solution, by simulating the change and influence of different grouting solutions, to evaluate the stability under different solutions, and find the optimal grouting solution. During the construction process, the Digital Twin technique can monitor the change of the grouting in real time combining with sensor data. Comparing the data collected by sensors with the digital model, abnormal conditions may be found and the grouting solutions may be adjusted in time. The combination of Digital Twin technique and grouting simulation can provide more information, support and prediction capabilities in grouting construction, help to optimize construction plans, reduce risks, and improve construction efficiency and quality.

(5) Inputting the data into a formed five-in-one ion model for evaluating layout effect of sensor based on twin entity, taking layout coverage, layout density, layout timeliness, monitoring continuity and local effect of the sensors as evaluation indexes, optimizing the layout through scoring the sensor layout according to the evaluation indexes, and finally selecting the optimal sensor layout solution.

In the present example, the layout coverage A₁, the layout density A₂, the layout timeliness A₃, the monitoring continuity A₄ and the local effect A₅ of the sensors are set as evaluation indexes;

Establish the scoring threshold standard of each index, and assign points to each evaluation index according to the actual data;

The wider the coverage, the smaller the density; the more timely the layout, the better the monitoring continuity; the more accurate the local hazard capture effect, and the higher the score. Based on this, combining with the actual collected data, the score threshold of the index is established, and the score is given for evaluation.

The sensor placement score in the present example is:

$$P = {k}_{1} {A}_{1} + {k}_{2} {A}_{2} + {k}_{3} {A}_{3} + {k}_{4} {A}_{4} + {k}_{5} {A}_{5} ,$$

where, k₁, k₂, k₃, k₄ and k₅ are the weights of each evaluation index respectively; A₁, A₂, A₃, A₄ and A₅ are the normalized scores of each evaluation index respectively.

By normalizing the evaluation index scores,

$$A = \frac{Actual Value - Minimum Value}{Maximum Value - Minimum Value} ,$$

a purpose thereof is to map the scores into the range of [0,1], which is convenient for multiplying with weights. The scores under each sensor layout solution are calculated separately, and the sensor layout solution with the highest score is selected as the optimal sensor layout solution.

Obtaining grouting data of practical engineering through the optimal sensor layout.

Furthermore, adjusting, by using control variable method, the parameters of grouting simulation module and multi-source geologic body attribute model, to obtain the multi-factor diffusion range with variable coefficients. In grouting process, the influence of these parameters on groundwater diffusion may be understood by adjusting different parameters, such as grouting pressure, slurry concentration, etc. At the same time, the parameters in the multi-source geologic body attribute model also are adjusted to simulate and analyze the diversity of underground geological structures. Through such adjustment, the correlation between different parameters can be obtained, especially the comprehensive influence of these parameters on the multi-factor diffusion range. After grouting, the diffusion and effectiveness of grouting can be directly proved from the core drilled in the treatment region. The diffusion situation of grouting slurry is initially obtained through multiple boreholes, the diffusion shape of the grouting slurry is obtained by calculation fitting, and the diffusion distance of the grouting slurry in 14 directions is comprehensively used to characterize the diffusion range, as shown in FIG. 3, where the numbers 1, 2, 3, . . . , 14 represent 14 different directions of slurry diffusion.

Wherein, obtaining the multi-factor diffusion range with variable coefficients by adjusting, using the control variable method, the parameter values in the grouting simulation module and the multi-source geologic body attribute model, and a calculation method of the diffusion range is as follows:

$$f ( {a}_{1} \times water inflow , {b}_{1} \times fracture density , {c}_{1} \times certain element content , {d}_{1} \times rock mass strength , {e}_{1} \times crustal stress , {g}_{1} \times grouting mdium pressure , {h}_{1} \times grouting slurry property , {k}_{1} \times grouting quantity ) = diffusion range .$$

Wherein, regulating and controlling, using the control variable method, the parameter values in the grouting simulation module and the multi-source geologic body attribute model, including:
a₁=f₁ (fracture density, certain element content, rock mass strength, crustal stress, grouting medium pressure, grouting slurry property, grouting quantity);
b₁=f₁ (water inflow, certain element content, rock mass strength, crustal stress, grouting medium pressure, grouting slurry property, grouting quantity);
c₁=f₁ (water inflow, fracture density, rock mass strength, crustal stress, grouting medium pressure, grouting slurry property, grouting quantity);
d₁=f₁ (water inflow, fracture density, certain element content, crustal stress, grouting medium pressure, grouting slurry property, grouting quantity);
e₁=f₁ (water inflow, fracture density, certain element content, rock mass strength, grouting medium pressure, grouting slurry property, grouting quantity);
g₁=f₁ (water inflow, fracture density, certain element content, rock mass strength, crustal stress, grouting slurry property, grouting quantity);
h₁=f₁ (water inflow, fracture density, certain element content, rock mass strength, crustal stress, grouting medium pressure, grouting quantity);
k₁=f₁ (water inflow, fracture density, certain element content, rock mass strength, crustal stress, grouting medium pressure, grouting slurry property);
where, f₁ is the function relation parameter, a₁, b₁, c₁, d₁, e₁, g₁, h₁, k₁ are the regulation coefficients.

Furthermore, a multi-layer convolutional neural network (CNN) is built to deal with the spatial features of parameters in grouting monitoring system and multi-source geologic body attribute model, and to learn and capture the complex mapping relationship between different parameters. And, a recurrent neural network (RNN) is introduced to deal with the temporal characteristics of the diffusion range to consider the evolution of parameters over time, and recording the dynamics of the diffusion process.

The CNN and RNN are combined to construct a multimodal mapping model to consider comprehensively complex correlation between parameter space domain (parameter space feature) and time domain (parameter time feature), to reveal the influence of multiple parameters on diffusion range. Further, a generative adversarial network (GAN) is introduced to optimize the generation ability of the model. The GAN may help the model generate the diversity of underground geological structure better, and improve the generalization and authenticity of the model. The multimodal mapping model is trained by using the dataset of numerical simulation system. During training, the model learns the mapping relationship between different parameters and feeds back through the GAN to optimize its ability to generate underground geological structures.

Wherein, a structure of the multimodal mapping model includes:
an input layer, including parameters in grouting simulation module and multi-source geologic body attribute model; wherein, the parameters contain grouting parameters such as grouting pressure and slurry concentration, and multiple geological attribute parameters in the underground geologic body structure model;
a multi-layer CNN, used to deal with the space domain of the parameters in the grouting monitoring system and underground geologic body structure model, to learn complex mapping relationship between different parameters;
the RNN, used to deal with the time domain of diffusion range, consider the evolution of parameters in time and record the dynamic characteristics of diffusion process;
the GAN, used to optimize the generation ability of the model and improve the diversity, generalization and authenticity of generated underground geological structures; and
an output layer, including attributes related to groundwater flow, such as the multifactor diffusion range and the like.

Further, in a module of the CNN, extracting spatial features of input parameters and learning complex relationships among parameters through multi-layer convolution and pooling layers. In a module of the RNN, processing time series data by using a cyclic structure, capturing the evolution of parameters in time, and recording the dynamic characteristics of diffusion process. In module of the GAN, generating more realistic and diverse underground geological structures by using generators and discriminators, to improve the generalization of the model.

The multimodal mapping model takes into account the characteristics of the CNN and RNN outputs and reveals the comprehensive influence of multiple parameters on the diffusion range.

The training process includes: training the model using the dataset of numerical simulation system, learning the mapping relationship between different parameters, and carrying out the feedback through GAN network to optimize the ability to generate underground geological structures.

Thus, obtaining the grouting parameters in the actual grouting engineering, setting a control module for the actual grouting engineering, calculating the diffusion range of the grouting slurry through the data collected by the pressure sensor, the flow monitor, the rock and soil deformation monitoring instrument and the ground penetrating radar (GPR). Wherein, the pressure sensor is used for monitoring the change of the grouting pressure in the grouting system in real time; by monitoring the grouting pressure, the system is able to analyze the permeability of grouting slurry in the underground rock and soil body, and capture critical pressure information during changing of the grouting process. The flow monitor is used for recording the flow rate of the grouting slurry in the grouting system; measuring the flow rate may help to determine the propagation rate of the grouting slurry in the underground and provide basic data for calculating the diffusion range. The rock and soil deformation monitoring instrument is used to monitor the deformation of the underground rock and soil body; by recording the displacements, deformations and deformations of the rock and soil body, the system can assess the effect of the grouting process on the underground structure and thus better analyze the diffusion range. The GPR is a non-intrusive subsurface exploration tool used to detect changes in underground structures; through the data collected by the GPR, detailed information about underground space and rock and soil properties can be obtained, which provides a more comprehensive geological background for the calculation of diffusion range. Inputting the parameters described above into the multimodal mapping system for training by using the specific method in step 5, driving the model to learn the mapping relationship among different parameters, carrying out the feedback through the GAN. When the engineering background is changed, adjusting physical quantities such as the level of groundwater table, fracture density, certain element content, rock mass strength, crustal stress and the like, inputting the ideal values for calculating the diffusion range of the grouting slurry, to obtain the optimal grouting pressure or slurry property, which optimizes the ability of generating underground geological structures, and realizes the pre-controlling and monitoring of the whole process of multimodal grouting.

### Example 2

An example of the present invention provides a pre-control and monitoring system for a whole process of an actual grouting engineering based on digital geological model, comprising:
a data acquisition module, configured to obtain underground borehole data and geological logging data;
an underground geologic body structure modeling module, configured to extract and mesh fracture surfaces in a stratum, calculate fractal dimension of the fracture surfaces, inspect a coplanarity of discontinuous fracture surfaces, and build a underground geologic body structure model;
a multi-source geologic body attribute modeling module, configured to extract multi-source attribute data values from images of surrounding rocks and the underground borehole data, divide the underground geologic body structure model into spatial grid units, assign the multi-source attribute data values to the underground geologic body structure model, to obtain a multi-source geologic body attribute model;
a tunnel risk assessment module, configured to build a underground engineering risk-assessment model to perform multi-factor disaster risk region assessment for each of the spatial grid units, to achieve a prediction of a high-risk region for geological disaster;
a grouting simulation module, configured to optimize and solve a grouting simulation for the high-risk region for geological disaster by using multiphase flow calculation method;
a multimodal grouting analysis module, configured to adjust the physical values of the grouting parameters by using a control variable method and based on the obtained diffusion range data of the grouting slurry, obtain a multi-factor diffusion range with variable coefficients in the actual grouting engineering; learn and capture a complex mapping relationship between different parameters by using a neural network, to monitor and optimize a whole process of the actual grouting engineering in real-time; and
an actual engineering control module, configured to control grouting equipment according to the optimized physical values of the grouting parameters obtained from the grouting simulation, to perform the actual grouting engineering on the predicted high-risk region for geological disaster; and configured to control the grouting equipment according to the real-time adjusted and optimized physical values of the grouting parameters, to complete the whole process of the actual grouting engineering.

### Example 3

An example of the present invention provides a terminal device, comprising a processor and a memory storing a plurality of instructions that, when executed by the processor, causes the processor to perform a pre-control and monitoring method for a whole process of an actual grouting engineering based on digital geological model described in the Example 1.

### Example 4

An example of the present invention provides a non-transitory computer-readable storage medium, storing a plurality of instructions that, when executed by a processor of a terminal device, causes the processor to perform a pre-control and monitoring method for a whole process of an actual grouting engineering based on digital geological model described in the Example 1.

The present invention is described with reference to flowcharts and/or block diagrams of methods, devices (systems), and computer program products according to the examples of the present invention. It should be understood that each of the processes and/or boxes in the flowchart and/or block diagram, and the combination of the processes and/or boxes in the flowchart and/or block diagram, may be implemented by computer program instructions. These computer program instructions may be provided to a processor of a general purpose computer, a specialized computer, an embedded processor, or other programmable data processing device to produce a machine such that the instructions executed by the processor of the computer or other programmable data processing device produce a device for implementing the functions specified in one process or multiple processes of the flowchart and/or one box or multiple boxes of the block diagram.

These computer program instructions may also be loaded onto a computer or other programmable data processing device to enable a series of operational steps to be performed on the computer or other programmable device to generate a computer implemented process, so that instructions executed on a computer or other programmable device provide steps for implementing functions specified in one process or a plurality of processes of the flowchart and/or in one box or a plurality of boxes of the block diagram.

Although the specific embodiments of the present invention are described above in combination with the accompanying drawings, it is not a limitation on the protection scope of the present invention. Those skilled in the art should understand that on the basis of the technical scheme of the present invention, various modifications or deformations that can be made by those skilled in the art without creative labor are still within the protection scope of the present invention.

1. A pre-control and monitoring method for a whole process of an actual grouting engineering based on digital geological model, comprising:
acquiring images of a tunnel face, performing image enhancement processing on the obtained images of the tunnel face, and extracting structure features of the tunnel face based on the enhanced images of the tunnel face;
laying sensors according to the extracted structure features of the tunnel face; wherein, the sensors comprise an acoustic signal sensor and nanosensors, wherein the acoustic signal sensor is fixed on the tunnel face and continuously monitor changes of a diffusion range of a grouting slurry in a grouting project;
carrying out underground drilling on a stratum within a range of a section to be excavated, obtaining underground borehole data and geological logging data, extracting and meshing fracture surfaces in the stratum, calculating fractal dimension of the fracture surfaces, inspecting a coplanarity of discontinuous fracture surfaces, and building an underground geologic body structure model;
extracting multi-source attribute data values from images of surrounding rocks and the underground borehole data, dividing the underground geologic body structure model into spatial grid units, assigning the multi-source attribute data values to the underground geologic body structure model, to obtain a multi-source geologic body attribute model;
building an underground engineering risk-assessment model to perform multi-factor disaster risk region assessment for each of the spatial grid units, to achieve a prediction of a high-risk region for geological disaster;
carrying out a grouting simulation for the high-risk region for geological disaster, and optimizing and solving the grouting simulation by using multiphase flow calculation method, obtaining optimized physical values of grouting parameters of grouting in the high-risk region for geological disaster;
controlling grouting equipment according to the optimized physical values of the grouting parameters, to perform an actual grouting engineering on the predicted high-risk region for geological disaster;
injecting the grouting slurry mixed with the nanosensors based on regional characteristics of the high-risk region for geological disaster into the section to be excavated, marking the nanosensors by using fluorescent substances; detecting fluorescent signals of the nanosensors by using fluorescence imaging technology after the nanosensors entering the section to be excavated;
obtaining diffusion range of the grouting slurry data in the actual grouting engineering by accurately tracking positions of the nanosensors in the grouting slurry by monitoring the fluorescent substances, and obtaining the diffusion range data of the grouting slurry in the actual grouting engineering;
adjusting the physical values of the grouting parameters in the grouting simulation and the multi-source geologic body attribute model by using a control variable method and based on the obtained diffusion range data of the grouting slurry, to obtain a multi-factor diffusion range with variable coefficients in the actual grouting engineering; learning and capturing a complex mapping relationship between different parameters by using a neural network, to monitor and optimize a whole process of an actual grouting engineering in real-time; and
controlling the grouting equipment according to the real-time adjusted and optimized physical values of the grouting parameters, to complete the whole process of an actual grouting engineering;
wherein, a geologic body structure comprises homogeneous geologic bodies and unfavorable geologic bodies; obtaining the homogeneous geologic bodies and unfavorable geologic bodies in the geological exploration data and geophysical exploration data by using a fitting method, embedding the unfavorable geologic bodies into an average geologic body structure, combining with the obtained discontinuous fracture surfaces, to complete the building of the underground geologic body structure model; and
taking the underground geologic body structure model as the geologic body structure, and uses multi-source attribute information as boundary conditions, to initialize settings of the grouting simulation; gridding an underground geologic body structure model to be calculated through calculation, setting a size of grids to be an integer multiple of a size of an unit body, maintaining a relationship between a number of the grids and calculation nodes of a server to be that each set number of the grids corresponds to one calculation node, and determining required calculation nodes according to the number of the grids.

2. The pre-control and monitoring method for the whole process of the actual grouting engineering based on digital geological model according to claim 1, wherein using the underground borehole data, through an integration of key parameters comprising at least core analysis, formation thickness and pore structure, transforming discrete borehole data into continuous subsurface rock and soil models by using an interpolation method; performing a image generation by using the geological logging data, and generating a stratigraphic profile diagram by deep analyzing information of rock character, structural characteristics and stratigraphic changes in the geological logging data by using an image processing technology and a geographic information system (GIS) technology; and, restoring the stratigraphic profile map and the subsurface rock and soil models to the underground geologic body structure by using three-dimensional (3D) modeling techniques.

3. The pre-control and monitoring method for the whole process of the actual grouting engineering based on digital geological model according to claim 1, wherein extracting the discontinuous fracture surfaces in the stratum, and calculating fracture fractal dimensions, comprises:
identifying borehole images based on machine vision technology, carrying out image processing and fractal dimension calculation; based on a principle of fractal geometry, measuring a complexity of the discontinuous fracture surfaces by using a fractal dimension calculation method;
gridding the extracted discontinuous fracture surfaces, inspecting a coplanarity for the discontinuous fracture surfaces, and building the underground geologic body structure model combining with an inspection result of the coplanarity inspection.

4. The pre-control and monitoring method for the whole process of the actual grouting engineering based on digital geological model according to claim 3, wherein extracting the discontinuous fracture surfaces in the stratum comprises: based on the underground borehole data and the geological logging data, obtaining each of the borehole images and point cloud information, identifying fractures by using a machine vision semantic segmentation model to obtain trace fractures, and obtaining fracture fractal dimension data by fitting the trace fractures.

5. The pre-control and monitoring method for the whole process of the actual grouting engineering based on digital geological model according to claim 1, wherein the discontinuous fracture surfaces of fractures of different boreholes have spatial correlation, and discontinuous fracture surface regions of two disconnected boreholes may be compatible with a same plane equation; inspecting a coplanarity for different discontinuous fracture surfaces by using obtained fracture fractal dimension data, to judge whether different discontinuous fracture surfaces belong to a same spatial plane dataset.

6. The pre-control and monitoring method for the whole process of the actual grouting engineering based on digital geological model according to claim 1, wherein obtaining multiple multi-source attribute information based on surrounding rock images, cognition data while drilling and in-situ test data; analyzing the multi-source attribute information to judge whether the multi-source attribute information is continuous data or not; obtaining the multi-source attribute data value by using different simulation methods according to the judgment result; dividing the underground geologic body structure model into the spatial grid units, assigning the multi-source attribute data values to the underground geologic body structure model, to obtain the multi-source geologic body attribute model.

7. The pre-control and monitoring method for the whole process of the actual grouting engineering based on digital geological model according to claim 1, wherein dividing a plurality of spatial grid units for the multi-source geologic body attribute model based on actual stored data of grouting engineering, to build the underground engineering risk-assessment model, and carrying out the multi-factor disaster risk region assessment on each of the spatial grid units, and the multi-factor disaster risk region assessment comprises: a surrounding rock grade assessment, a crustal stress assessment, a water and mud inrush assessment and a grouting region assessment; then predicting the disaster high-risk regions, and carrying out the grouting simulation on the predicted disaster high-risk regions.

8. The pre-control and monitoring method for the whole process of the actual grouting engineering based on digital geological model according to claim 1, wherein carrying out and solving the grouting simulation by using a multiphase flow calculation method, comprises: establishing momentum equations and continuity equations; describing a viscosity change of the grouting slurry in grouting process and building a calculation model of transmission time; establishing boundary conditions being set by changes of velocity and pressure; changing a position, size, shape and quantity of a grouting inlet of a calculation model to simulate an effect of different grouting methods of compaction grouting and curtain grouting, to simulate a diffusion of grouting slurry under different construction technology conditions; simulating the diffusion of the grouting slurry under space-time dual-variable conditions for different slurry types according to time-varying function of slurry increasing-different viscosity; conducting a sectional grouting simulation of the calculation model, and setting other parameters of grouting in each section.

9. The pre-control and monitoring method for the whole process of the actual grouting engineering based on digital geological model according to claim 8, wherein simulating and calculating different grouting parameter combinations by using a numerical simulation, during the simulation and calculation, changing the grouting parameters in a grouting simulation system and different attribute values in the multi-source attribute geological model, and keeping one grouting parameter changing in the different grouting parameter combinations.

10. The pre-control and monitoring method for the whole process of the actual grouting engineering based on digital geological model according to claim 9, wherein according to an effect value of one grouting effect, calculating an optimal addition value of each of the grouting parameters to the grouting effect, expressing the calculation as a matrix equation and solving; solving the matrix equation above by selecting a plurality of groups of numerical simulation grouting solution data to obtain optimized bonus values of the plurality of groups of grouting parameters, and calculating the final optimized bonus values of the grouting parameters by averaging the optimized bonus values of the plurality of groups of grouting parameters.

11. The pre-control and monitoring method for the whole process of the actual grouting engineering based on digital geological model according to claim 10, wherein optimizing a grouting solution on a basis of existing numerical simulation grouting solution data by using particle swarm optimization algorithm, wherein each simulated grouting solution parameter is regarded as particle as initialization data, and attached attributes thereof are current grouting parameter configuration and achieved grouting effect; carrying out an iterative calculation, setting iterative steps to loop the iterative calculation until a final step, to output an overall optimal solution.

12. The pre-control and monitoring method for the whole process of the actual grouting engineering based on digital geological model according to claim 1, wherein building mapping relationships between the grouting simulation and multi-parameters in the multi-source geologic body attribute model, building a multi-layer convolutional neural network (CNN) to deal with spatial features of parameters in the grouting simulation and the multi-source geologic body attribute model, and to learn and capture a complex mapping relationship between different parameters; introducing a recurrent neural network (RNN) to deal with a time domain of the diffusion range to consider the evolution of parameters over time.

13. The pre-control and monitoring method for the whole process of the actual grouting engineering based on digital geological model according to claim 12, wherein combining the CNN and RNN to construct a multimodal mapping model to consider a complex correlation between the space domain and the time domain of the parameters, introducing a generative adversarial network to optimize a generation ability of model; learning the mapping relationship between the different parameters and feeding back through the GAN, to optimize an ability of generating the underground geologic body structures.

14. A pre-control and monitoring system for a whole process of an actual grouting engineering based on digital geological model, comprising:
a data acquisition module, configured to obtain underground borehole data and geological logging data;
an underground geologic body structure modeling module, configured to extract and mesh fracture surfaces in a stratum, calculate fractal dimension of the fracture surfaces, inspect a coplanarity of discontinuous fracture surfaces, and build a underground geologic body structure model; wherein, a geologic body structure comprises homogeneous geologic bodies and unfavorable geologic bodies; obtaining the homogeneous geologic bodies and unfavorable geologic bodies in the geological exploration data and geophysical exploration data by using a fitting method, embedding the unfavorable geologic bodies into an average geologic body structure, combining with the obtained discontinuous fracture surfaces, to complete the building of the underground geologic body structure model;
a multi-source geologic body attribute modeling module, configured to extract multi-source attribute data values from images of surrounding rocks and the underground borehole data, divide the underground geologic body structure model into spatial grid units, assign the multi-source attribute data values to the underground geologic body structure model, to obtain a multi-source geologic body attribute model;
a tunnel risk assessment module, configured to build a underground engineering risk-assessment model to perform multi-factor disaster risk region assessment for each of the spatial grid units, to achieve a prediction of a high-risk region for geological disaster;
a grouting simulation module, configured to optimize and solve a grouting simulation for the high-risk region for geological disaster by using multiphase flow calculation method; wherein, taking the underground geologic body structure model as the geologic body structure, and uses multi-source attribute information as boundary conditions, to initialize settings of the grouting simulation; gridding an underground geologic body structure model to be calculated through calculation, setting a size of grids to be an integer multiple of a size of an unit body, maintaining a relationship between a number of the grids and calculation nodes of a server to be that each set number of the grids corresponds to one calculation node, and determining required calculation nodes according to the number of the grids;
a multimodal grouting analysis module, configured to adjust the physical values of the grouting parameters by using a control variable method and based on the obtained diffusion range data of the grouting slurry, obtain a multi-factor diffusion range with variable coefficients in the actual grouting engineering; learn and capture a complex mapping relationship between different parameters by using a neural network, to monitor and optimize a whole process of an actual grouting engineering in real-time; and
an actual engineering control module, configured to control grouting equipment according to the optimized physical values of the grouting parameters obtained from the grouting simulation, to perform an actual grouting engineering on the predicted high-risk region for geological disaster;
and configured to control the grouting equipment according to the real-time adjusted and optimized physical values of the grouting parameters, to complete the whole process of the actual grouting engineering.

15. A terminal device, comprising a processor and a memory storing a plurality of instructions that, when executed by the processor, causes the processor to load and perform a pre-control and monitoring method for a whole process of an actual grouting engineering based on digital geological model according to claim 1.

16. A non-transitory computer-readable storage medium, storing a plurality of instructions that, when executed by a processor of a terminal device, causes the processor to load and perform a pre-control and monitoring method for a whole process of an actual grouting engineering based on digital geological model according to claim 1.
